(19) United States
(12) Patent Application Publication
(10) Pub. No.: US 2024/0194726 A1
(43) Pub. Date: Jun. 13, 2024

(54) LIGHT-EMITTING DEVICE AND DISPLAY DEVICE

(71) Applicant: EPISTAR CORPORATION, Hsinchu (TW)

(72) Inventors: Chun-Chang CHEN, Hsinchu (TW); I-Tsung CHEN, Hsinchu (TW)

(21) Appl. No.: 18/529,961

(22) Filed: Dec. 5, 2023

(30) Foreign Application Priority Data
Dec. 8, 2022 (CN) 202211569050.2

(51) Int. Cl. H01L 27/15

(52) U.S. Cl. CPC H01L 27/156

(57) ABSTRACT

The present application provides a light-emitting device, which comprises a circuit carrier board and a first light-emitting element group. The first light-emitting element group includes a plurality of light-emitting elements on the circuit carrier board. The light-emitting elements each include a substrate, which has a first surface, a second surface opposite to the first surface, first and second lateral surfaces that are paired and oppositely arranged. The second surfaces each face the circuit carrier board. The light-emitting elements are on the circuit carrier board along a first direction and the second lateral surfaces of the adjacent two of them face each other. A formula: |θ₁−90°|>|θ₂−90°| is satisfied, wherein θ₁ is the included angle between the first lateral surface and the first surface, and θ₂ is the included angle between the second lateral surface and the first surface.

### CROSS REFERENCE TO RELATED APPLICATIONS

This application claims priority to the benefit of China Patent Application Number 202211569050.2 filed on Dec. 8, 2022, and the entire content of which is hereby incorporated by reference herein in its entirety.

### TECHNICAL FIELD

The present application relates to a light-emitting device, and more particularly, to a light-emitting device comprising light-emitting diodes and a display device.

### DESCRIPTION OF BACKGROUND ART

With the continuous development of LED (light-emitting diode) display technology, image resolution of display has been continuously enhanced. In order to enhance the image resolution, a conventional approach is to reduce the pitch of adjacent light-emitting diodes to accommodate more light-emitting diodes in unit area, thus increasing the pixel density per unit area. Generally speaking, when arranging light-emitting diodes, a die bonder is used for mounting the light-emitting diodes at predetermined positions.

Considering the alignment error of the die bonder and the exterior appearance differences, such as broken dies, inconsistent die size after dicing, and the oblique side walls of the die, during the die bonding process, when the pitch of adjacent light-emitting diodes becomes smaller and smaller, adjacent light-emitting diodes may easily collide, impacting the product yield rate.

### SUMMARY OF THE APPLICATION

To solve the aforementioned technical problems, a light-emitting device and a display device of the present application are provided.

According to an embodiment of the present application, a light-emitting device is provided to comprise a circuit carrier board and a first light-emitting element group. The first light-emitting element group comprises a plurality of light-emitting elements on the circuit carrier board. Wherein the light-emitting elements each comprise a substrate. The substrate each comprises a first surface, a second surface opposite to the first surface, first lateral surfaces that are paired and oppositely arranged, and second lateral surfaces that are paired oppositely arranged. The second surface each faces the circuit carrier board. Each of the second lateral surfaces comprises an edge, and each of the second surfaces connects the first surface by the edge. Wherein the plurality of light-emitting elements is arranged on the circuit carrier board along a first direction. Adjacent two of the plurality of light-emitting elements are provide with the second lateral surfaces face each other. The first direction is not parallel to the edge, and a formula: |θ₁−90°|>|θ₂−90°| is satisfied. Wherein the θ₁ is an included angle between the first lateral surfaces and the first surface, and the θ₂ is an included angle between the second lateral surfaces and the first surface.

According to another embodiment of the present application, a display device is provided, and it comprises a plurality of pixels. The pixels comprise the aforementioned light-emitting devices.

According to another embodiment of the present application, a light-emitting device is provided to comprise a circuit carrier board and a first light-emitting element group. The first light-emitting element group comprises a first light-emitting element, a second light-emitting element, and a third light-emitting element on the circuit carrier board. The first, second and third light-emitting elements each comprise a substrate. The substrate each comprises a first surface, a second surface opposite to the first surface, first lateral surfaces that are paired and oppositely arranged, and second lateral surfaces that are paired and oppositely arranged. The second surface faces the circuit carrier board. In a top view toward the first surface, the first lateral surfaces each is provided with a length smaller than a length of the second lateral surfaces. The first light-emitting element is adjacent to the second light-emitting element, and one of the first lateral surfaces of the first light-emitting element faces one of the second lateral surfaces of the second light-emitting element. The second light-emitting element satisfies a formula: |θ₁−90°|>|θ₂−90°|. Wherein the θ₁ is an included angle defined between each of the first lateral surfaces and the first surface of the second light-emitting elements, and the θ₂ is another included angle defined between each of the second lateral surfaces and the first surface of the second light-emitting elements.

The embodiments of the present application may be more fully understood by reading the subsequent detailed description and examples with references made to the accompanying drawings.

### BRIEF DESCRIPTION OF THE DRAWINGS

Aspects of the present disclosure are best understood from the following detailed description when read with the accompanying figures. Through the specific embodiments and the corresponding figures of the disclosure, the detail of the specific embodiments and the action principles of the present disclosure are thus better illustrated. In addition, for the sake of clarity, the features each of the figures may not be drawn in accordance with practical scale. The size of some of the features in the figures may be deliberately scaled up or down.

FIG. 1 is an aerial schematic view of a light-emitting device in accordance with an embodiment of the present application.

FIG. 2 is a cross-sectional schematic view of the light-emitting device taken along cross-sectional lines A-A′, B-B′, and C-C′ of FIG. 1 in accordance with an embodiment of the present application.

FIG. 3 is a cross-sectional schematic view of the light-emitting device taken along cross-sectional line D-D′ of FIG. 1 in accordance with an embodiment of the present application.

FIG. 4 is another cross-sectional schematic view of the light-emitting device taken along the cross-sectional lines A-A′, B-B′, and C-C′ of FIG. 1 in accordance with some embodiments of the present application.

FIG. 5 is an aerial schematic view of a light-emitting device in accordance with an embodiment of the present application.

FIG. 6 is an aerial schematic view of a light-emitting device in accordance with an embodiment of the present application.

FIG. 7 is a cross-sectional schematic view of the light-emitting device taken along cross-sectional lines E-E′ and F-F′ of FIG. 6 in accordance with an embodiment of the present application.

FIGS. 8-10 are aerial schematic views of light-emitting devices in accordance with some embodiments of the present application.

FIG. 11 is a cross-sectional schematic view of the light-emitting device taken along the cross-sectional lines D-D′ of FIG. 1 in accordance with an embodiment of the present application.

FIG. 12 is a perspective schematic view of a display device in accordance with an embodiment of the present application.

### DETAILED DESCRIPTION OF PREFERRED EMBODIMENTS

Aspects of the present disclosure are best understood from the following detailed description when read with the accompanying figures. Through the specific embodiments and the corresponding figures of the disclosure, the detail of the specific embodiments and the action principles of the present disclosure are thus better illustrated. In addition, for the sake of clarity, the features each of the figures may not be drawn in accordance with practical scale. The size of some of the features in the figures may be deliberately scaled up or down.

The following disclosure provides many different embodiments or examples for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed indirect contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relation between the various embodiments and/or configurations discussed.

Further, spatially relative terms, such as “beneath,” “below,” “lower,” “over,” “above,” “upper” and the like, may be used herein for ease of description to describe the relation of one element or feature to another element(s) or feature(s) as illustrated in the figures. The spatially relative terms are intended to encompass different orientations of the semiconductor device in use or operation in addition to the orientation depicted in the figures. For example, if the semiconductor device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or manufacturing order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

The “group III-V compound semiconductor” indicated in the present application means the compound semiconductor comprising one group III element and one group V element. The group III element may include boron, aluminum, gallium, or Indium. The group V element may include nitrogen, phosphorous, arsenic, or bismuth. Further, the “group III-V compound semiconductor” may be, but not limited to, binary compound semiconductor (e.g., aluminum nitride (AlN), gallium nitride (GaN), indium phosphide (InP), aluminum arsenide (AlAs) or gallium arsenide (GaAs)), ternary compound semiconductor (e.g., aluminum gallium nitride (AlGaN), indium gallium nitride (InGaN), gallium indium phosphide (GaInP), aluminum gallium arsenide (AlGaAs), indium aluminum arsenide (InAlAs), or indium gallium arsenide (InGaAs)), quaternary compound semiconductor (e.g., indium aluminum gallium nitride (inAlGaN) or aluminum indium gallium phosphide (AlInGaP)), higher composition compound semiconductor or a combination thereof. Depending on the needs, the group III-V compound semiconductor may also comprise dopants to have specific electric conductivity, such as N-type or P-type conductivity.

Although the disclosure below is described with respect to specific embodiments, the principles of the present application, as defined by the claims appended herein, can obviously be applied beyond the specifically described embodiments of the present application described herein. Moreover, in the description of the present application, certain details have been left out in order to not obscure the inventive aspects of the disclosure. The details left out are within the knowledge of a person of ordinary skill in the art.

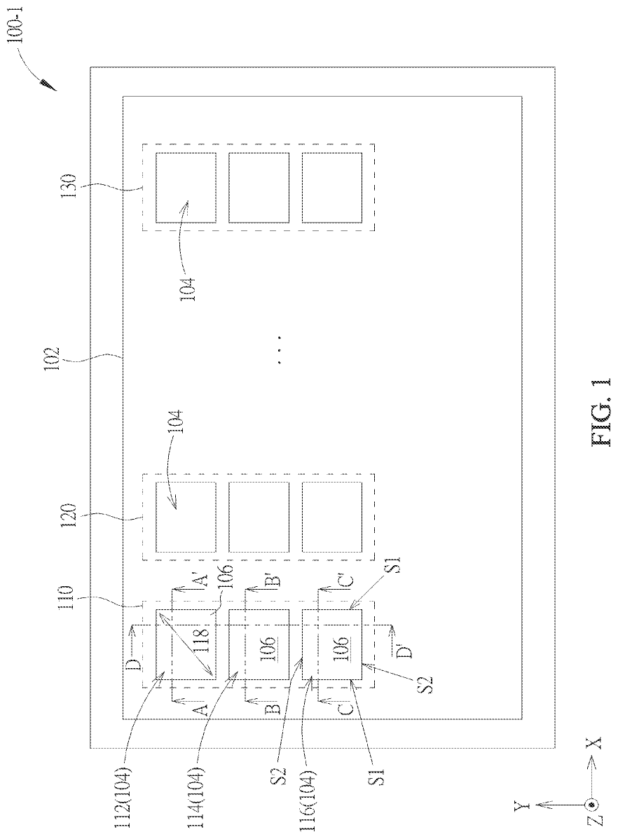

FIG. 1 is an aerial schematic view of a light-emitting device of an embodiment of the present application. Taking reference to FIG. 1, the light-emitting device 100-1 comprises a circuit carrier board 102 and a plurality of light-emitting elements 104 (e.g., light-emitting diodes) disposed on the circuit carrier board 102. Each of the light-emitting elements 104 may serve as a sub-pixel of a display device or as a light-emitting unit of a back-light module or an illuminating device.

The circuit carrier board 102 may be any carrier board having electric conducting circuit and electrically connecting each of the light-emitting elements 104, such as a first light-emitting element 112, a second light-emitting element 114 and a third light-emitting element 116, within a first light-emitting element group 110. The circuit carrier board 102 may be, for instance a printed circuit board (PCB), a flexible printed circuit board (FPCB), a transparent substrate made by organic materials, or a glass substrate. According to an embodiment of the present application, the light-emitting elements 104 on the circuit carrier board 102 may be a chip in a flip-chip form adopting chip-on-board (COB) technology or chip-on-glass (COG) technology to solder the light-emitting elements 104 on the surface of the electric conducting circuit of the circuit carrier board 102 through the manner of flip chip bonding. Compared to general wire bonding technology, when chip-on-board technology or chip-on-glass technology is utilized, the light-emitting element density per unit area can be further increased, and the electric connection reliability between the light-emitting elements 104 and the circuit carrier board 102 can be enhanced.

A plurality of the light-emitting elements 104 disposed on the circuit carrier board 102 may be arranged in an appropriate layout and constitute one light-emitting element group (e.g., first light-emitting element group 110) or a plurality of light-emitting element groups (e.g., first light-emitting element group 110, second light-emitting element group 120 . . . and nth light element group, where n is a positive integer larger than two). According to an embodiment of the present application, a single one light-emitting element group can serve as a single pixel on the circuit carrier board 102, and the plurality of light-emitting element groups can serve as the pixels of the display device respectively. For instance, the first light-emitting element group 110 serves as first pixel, the second light-emitting element group 120 serves as second pixel, and the nth light-emitting element group 130 serves as nth pixel while each one of the light-emitting elements 104 within the light-emitting element group can serve as a sub-pixel in the pixel. In one embodiment, the plurality of the light-emitting element groups may share the same circuit carrier board 102 and constitute a single package (namely all-in-one package). According to an embodiment of the present application, the layout of the plurality of light-emitting element groups is not limited to be configured as a single row. It may be configured as an array having multiple rows as well.

According to an embodiment of the present application, each of the light-emitting element groups 110, 120, 130 may comprise a plurality of light-emitting elements 104 (e.g., at least three light-emitting elements 104 or more than four light-emitting elements 104 in accordance with different needs). For the light-emitting elements 104 within the first light-emitting element group 110, the adjacent light-emitting elements 104 may be separated from each other to constitute a pitch. In addition, when the light-emitting elements 104 are observed by naked eye or by instrument, each of the light-emitting elements 104 can generate a predetermined visible light respectively. According to an embodiment of the present application, for the light-emitting elements 104 within the first light-emitting element group 110, the first light-emitting element 112 emits blue light, the second light-emitting element 114 emits green light, and the third light-emitting element 116 emits red light. In addition, in one embodiment, when the quantity of the light-emitting elements 104 within the first light-emitting element group 110 is more than three, at least two of the light-emitting elements 104 emit light with the same color. In another embodiment, when the quantity of the light-emitting elements 104 within the first light-emitting element group 110 is equal to three, all of the light-emitting elements 104 emit light with different colors.

For the light-emitting elements 104 within the first light-emitting element group 110, each of the light-emitting elements 104 comprises a substrate 106. The substrate 106 each comprises a first surface (not shown) and a second surface (not shown), first lateral surfaces S1 that are paired and arranged oppositely, and second lateral surfaces S2 that are paired and arranged oppositely. According to an embodiment of the present application, the first surface and the second surface of each of the substrates 106 are arranged along the Z-axis direction. The first surface is far from the circuit carrier board 102, while the second surface faces the circuit carrier board 102.

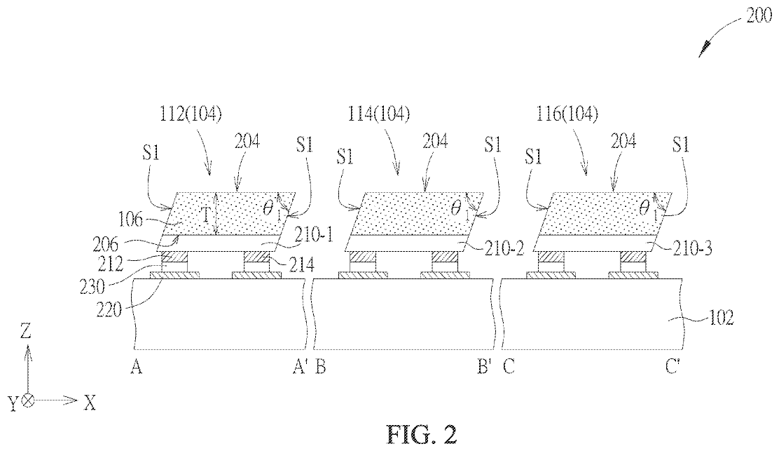

The second lateral surfaces each comprise an edge, and the first surface connects the second lateral surfaces S2 each by the edge. The pair of the first lateral surfaces S1 of each substrate 106 is arranged along the X-axis direction, while the pair of the second lateral surfaces S2 of each substrate 106 is arranged along the Y-axis direction. The plurality of light-emitting elements 104 is arranged along a first direction (e.g., the Y-axis direction) on the circuit carrier board 102, and the first direction (e.g., Y-axis direction) is not parallel to the edge between the first surface and the second lateral surfaces S2. The lateral surfaces S2 of any two adjacent light-emitting elements 104 of the plurality of light-emitting elements 104 arranged along the first direction face each other. For instance, for the adjacent first and second light-emitting elements 112, 114, one of the second lateral surfaces S2 of the first light-emitting element 112 faces one of the second lateral surfaces S2 of the second light-emitting element 114. For the adjacent second and third light-emitting elements 114, 116, the other second lateral surface S2 of the second light-emitting element 114 faces one of the second lateral surfaces S2 of the third light-emitting element 116. According to an embodiment of the present application, when the first light-emitting element group 110 is observed in the aerial view direction, e.g., the Z-axis direction, each of the substrates 106 of the light-emitting elements 104 comprises a short side and a long side. The short side and the long side are disposed on the first lateral surface S1 and the second lateral surface S2 respectively, but they are not limited to this arrangement. According to another embodiment of the present application, the short side may be on the second lateral surface S2, and the long side may be on the first lateral surface S1. According to an embodiment of the present application, when observed in the aerial view, each of the first surfaces 204 (see FIG. 2) of the substrates 106 comprises a diagonal 118, and the length of the diagonal 118 is not greater than 300 μm. Each of the substrates 106 may be a sapphire substrate or other suitable semiconductor substrate. Each of the first lateral surface S1 of the substrates 106 may be on or parallel to a specific crystal face (e.g., r-plane) of the sapphire substrate, while the second lateral surface S2 may be on or parallel to another specific crystal face (e.g., a-plane) of the sapphire substrate.

FIG. 2 is a cross-sectional schematic view of the light-emitting device taken along cross-sectional lines A-A′, B-B′ and C-C′ shown in FIG. 1 in accordance with an embodiment of the present application. Taking reference to FIG. 2, which schematically illustrates a cross-sectional structure 200 of the first light-emitting element 112, the second light-emitting element 114, and the third light-emitting element 116 on the X-Z plane. According to an embodiment of the present application, the first light-emitting element 112, the second light-emitting element 114, and the third light-emitting element 116 have similar structures, and their substrates 106 each comprise the first surface 204 far from the circuit carrier board 102 and the second surface 206 facing the circuit carrier board 102. The first light-emitting element 112, the second light-emitting element 114, and the third light-emitting element 116 each comprise semiconductor stacks 210-1, 210-2, 210-3 disposed on the second surface 206 of each substrate 106 respectively. The semiconductor stacks 210-1, 210-2, 210-3 each comprise a first semiconductor layer (not shown in the figure), a light-emitting layer (not shown in the figure), and a second semiconductor layer (not shown in the figure). The first and second semiconductor layers comprise different dopants with different electric conductivity respectively, e.g., n-type dopant and p-type dopant, so that the first and second semiconductor layers can provide electrons and electric holes respectively. According to an embodiment of the present application, the light-emitting layer of each of the semiconductor stacks 210-1, 210-2, 210-3 may be a group III-V compound semiconductor light-emitting layer, and the constituent materials and the constituent composition of the light-emitting layer of the semiconductor stacks may differ from each other. Therefore, when the semiconductor stacks 210-1, 210-2, 210-3 are supplied with biasing voltage, the first light-emitting element 112, the second light-emitting element 114, and the third light-emitting element 116 may generate light with different wavelengths. For instance, the first light-emitting element 112 emits blue light, the second light-emitting element 114 emits green light, and the third light-emitting element 116 emits red light. According to another embodiment of the present application, one or more of the first light-emitting element 112, the second light-emitting element 114, and the third light-emitting element 116 may be combined with a wavelength conversion layer (not shown in the figure). For instance, if the first light-emitting element 112, the second light-emitting element 114, and/or the third light-emitting element 116 emit UV light, one wavelength conversion layer may cover the surface of the light-emitting elements 112, 114, 116 or the wavelength conversion layer may be included in the package module afterward, so that the UV light emitted from each of the light-emitting elements 112, 114, 116 transmits into the corresponding wavelength conversion layer, and the wavelength conversion layer absorbs and converts the UV light to visible light with different wavelengths, e.g., blue light, green light, or red light.

As shown in FIG. 2, the light-emitting elements 104 each comprise one electrode, e.g., a first electrode 212 and a second electrode 214, electrically connecting the semiconductor stacks 210-1, 210-2, 210-3. The first electrode 212 is electrically connected with the first semiconductor layer, and the second electrode 214 is electrically connected with the second semiconductor layer. The first electrode 212 and the second electrode 214 may be supplied by different biasing voltage, so as to form a voltage differential between the first electrode 212 and the second electrode 214. The first electrode 212 and the second electrode 214 may comprise one metallic material selected from nickel (Ni), chromium (Cr), indium (In), rhodium (Rh), tin (Sn), titanium (Ti), platinum (Pt), palladium (Pd), silver (Ag), gold (Au), aluminum (Al), copper (Cu), an alloy of the aforementioned metallic materials. The first and second electrodes 212, 214 may be structured as a stacking layer with sub-layers made by the aforementioned metallic materials as well. In an embodiment, a transparent electric conducting material may be further provided between the first electrode 212 (and/or the second electrode 214) and the semiconductor stack 210-1, 210-2, or 210-3. The transparent electric conducting material is selected from metal oxide, light transmittable metal, graphene, etc. The first electrode 212 and the second electrode 214 may be electrically connected to electrode pads 220 by means of flip-chip. The electrode pads 220 are disposed on the circuit carrier board 102 and may be electrically connected to electric conducting circuit (not shown in the figures) of the circuit carrier board 102. The constituent material of the electrode pad 220 may comprise aluminum. The constituent material of the electrode pad 220 may comprise other electric conducting metal or transparent electric conducting material as well, such as ITO or other semiconductor material, depending on practical needs. Multiple electric conducting connection layers 230 are disposed between the electrodes 212, 214 and the electrode pads 220, so that the electrodes 212, 214 are fixedly connected to the electrode pads 220 and forms electric connection. The electric conducting connection layer 230 comprises solder material, electric conducting adhesive material, or eutectic material, depending on practical needs.

In general, under the condition of the same substrate oblique crack angle, the thicker the substrate 106 is, the longer the oblique crack length could be. According to an embodiment of the present application, each of the substrates 106 has a thickness T in the Z-axis direction, and the thickness T is not less than 40 μm and not greater than 100 μm. In an embodiment, the thickness T of each substrate 106 in the Z-axis direction is not less than 40 μm and not greater than 80 μm. By setting the thickness T of the substrate 106 within a specific range, the oblique crack length generated on the lateral surface (e.g., the first lateral surface) of the substrate 106 on the specific crystal face (e.g., r-plane) can be controlled, whereby preventing any two adjacent light-emitting elements 104 from colliding when they are bonded to the circuit carrier board 102. The cross-section of each substrate 106 is provided with two top angles that are defined between the first lateral surfaces S1 and the first surface 204. One of the top angles is an acute angle (namely the included angle θ₁), while the other top angle is an obtuse angle. According to an embodiment of the present application, when the substrate 106 is a sapphire substrate, the first lateral surfaces S1 correspond to or are parallel to a r-plane of the sapphire substrate, while the second surface 206 corresponds to a c-plane of the sapphire substrate. The first surface 204 is substantially parallel to the second surface 206, so the first surface 204 is substantially parallel to the c-plane. Since the r-plane and the c-plane of sapphire substrate are not vertical to each other, when sapphire substrate is used for the substrates 106 of the light-emitting elements 104, the light-emitting elements 104 each comprise the first surface 204 and the pair of the first lateral surfaces S1 inclined to the first surface 204.

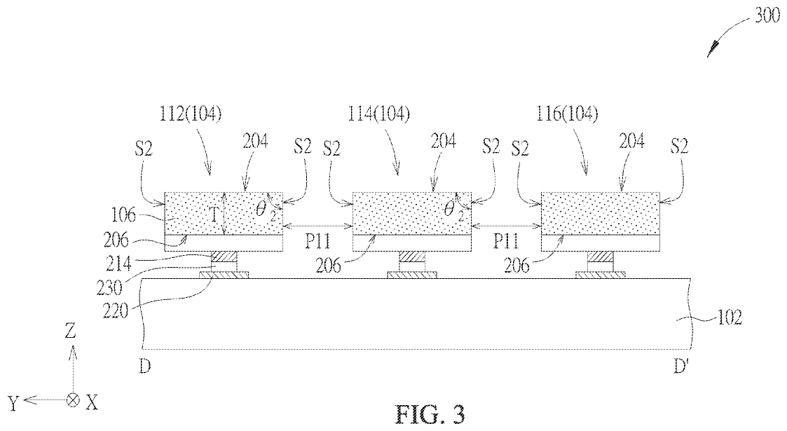

FIG. 3 is a cross-sectional schematic view of the light-emitting device taken along a cross-sectional line D-D′ shown in FIG. 1 in accordance with an embodiment of the present application. Taking reference to FIG. 3, which is a cross-sectional schematic view of the first light-emitting element 112, the second light-emitting element 114, and the third light-emitting element 116 on the Y-Z plane of a cross-sectional structure 300. The cross-section of each of the substrates 106 has two top angles defined between the second lateral surfaces S2 and the first surface 204, and the top angles are each (namely the included angle θ₂) between eighty-five to ninety-five degrees, which can be therefore substantially regarded as a right angle. According to an embodiment of the present application, when the substrate 106 is a sapphire substrate, the second lateral surfaces S2 correspond to or are parallel to an a-plane of the sapphire substrate, while the second surface 206 corresponds to the c-plane of the sapphire substrate. The first surface 204 is substantially parallel to the second surface 206. Since the a-plane and the c-plane of the sapphire substrate are vertical to each other, when sapphire substrate is used for the substrates 106 of the light-emitting elements 104, the light-emitting elements 104 each comprise the first surface 204 that is horizontal and the pair of the second lateral surfaces that are vertical to the first surface 204.

According to an embodiment of the present application, since the second lateral surfaces S2 of adjacent two light-emitting elements 104 that face each other are substantially vertical to the first surface 204 and the second surface 206, other than inclined to the first surface 204 and the second surface 206, the pitch (namely a first pitch P11) between the second lateral surfaces S2 of adjacent two light-emitting elements 104 that face each other can be ranged from 10 μm to 50 μm. According to an embodiment of the present application, the value of the first pitch P11 is less than the thickness of the substrate 106. In addition, since the second lateral surfaces S2 of adjacent two light-emitting elements 104 that face each other are substantially vertical to the first surface 204, during the manufacturing processes of the light-emitting device, when die bonder is used for mounting the light-emitting elements 104 on the circuit carrier board 102, the die bonder can easily recognize the actual positions of the second lateral surfaces S2 that face each other to reduce the probability or the degree of alignment error, further preventing adjacent light-emitting elements 104 from collision due to the inclination of the lateral surfaces of their substrates 106. Therefore, in accordance with an embodiment of the present application, even the first pitch P11 is reduced to the range from 10 μm to 50 μm, the production yield rate and product reliability are not impacted.

Referring to FIG. 2 and FIG. 3 together, the relation of the included angle θ₁ and the included angle θ₂ satisfies the following formula (1):

|θ₁−90°|>θ₂−90°| (1)

Wherein the included angle θ₁ is the included angle defined between the first lateral surfaces S1 and the first surface 204, and the included angle θ₂ is the included angle defined between the second lateral surfaces S2 and the first surface 204.

According to an embodiment of the present application, when each of the substrates 106 is formed and separated by laser dicing (e.g., stealth dicing) performed on a wafer, such as sapphire wafer, each of the first lateral surfaces S1 and each of the second lateral surfaces S2 of the light-emitting elements 104 can comprise modified trace units caused by laser focusing inside the substrates 106. In addition, in an embodiment, since the first lateral surfaces S1 and the second lateral surfaces S2 correspond to or are parallel to different crystal faces, different laser dicing conditions are required to form the predetermined structure of the first lateral surfaces S1 and the second lateral surfaces S2. For instance, when the first lateral surfaces S1 and the second lateral surfaces S2 are set to be separated from sapphire wafer along the specific crystal face, the laser irradiating times applied to a direction that the first lateral surface S1 extends to different depths (i.e. Z-axis direction) is different from the laser irradiating times applied to a direction that the second lateral surface S2 extends to different depths so the quantity of the modified trace units on the first lateral surfaces S1 is different from the quantity of the modified trace units on the second lateral surfaces S2. According to an embodiment of the present application, since the first lateral surfaces S1 correspond to or are parallel to the r-plane of the sapphire and the second lateral surfaces S2 correspond to or are parallel to the a-plane of the sapphire, higher laser irradiation power or more laser irradiation times at different depths are therefore required to dice and expose the first lateral surfaces S1. Thus, the quantity of the modified trace units on the first lateral surfaces S1 is greater than the quantity of the modified trace units on the second lateral surfaces S2. In other embodiments, the laser dicing condition may be adjusted in accordance with the thickness of the substrate 106. When the thickness of the substrate 106 is larger, the laser irradiating times applied on the second lateral surface S2 may be equal to the laser irradiating times applied on the first lateral surface S1 to ensure the dicing yield. Therefore, the quantity of the modified trace units on the first lateral surface S1 is equal to the one on the second lateral surface S2.

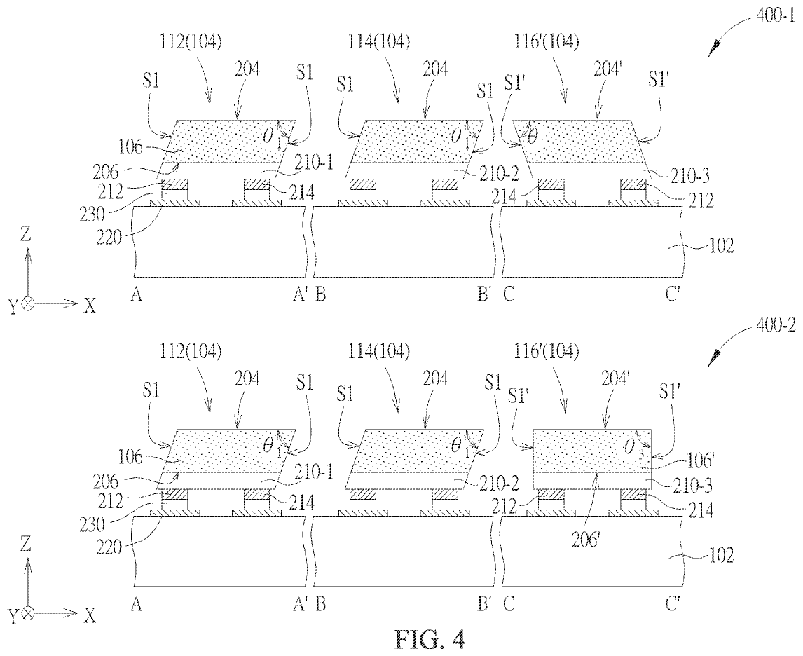

FIG. 4 is a cross-sectional schematic view of the light-emitting device taken along the cross-sectional lines A-A′, B-B′ and C-C′ shown in FIG. 1 in accordance with some embodiments of the present application. In FIG. 4, different cross-sectional structures of the first light-emitting element 112, the second light-emitting element 114, and a third light-emitting element 116′ of a first cross-sectional structure 400-1 and a second cross-sectional structure 400-2 respectively are shown in accordance with different embodiments.

For the first cross-sectional structure 400-1, its structure is similar to the cross-sectional structure 200 shown in FIG. 2. One of the differences between the two cross-sectional structures is that the placement direction of the third light-emitting element 116′ of the cross-sectional structure 400-1 differs from the placement direction of the third light-emitting element 116 of the cross-sectional structure 200. As shown in FIG. 4, the first surface 204′ of the third light-emitting element 116′, for instance, is parallel to the c-plane of the sapphire, and the first lateral surfaces S1′ of the third light-emitting element 116′, for instance, are parallel to the r-plane of the sapphire. In addition, the inclination direction of the first lateral surfaces S1′ of the third light-emitting element 116′ is opposite to the inclination direction of the first lateral surfaces S1 of the second light-emitting element 114.

For the second cross-sectional structure 400-2, its structure is similar to the cross-sectional structure 200 shown in FIG. 2. One of the differences between the two cross-sectional structures is that the substrate 106′ of the third light-emitting element 116′ of the second cross-sectional structure 400-2 comprises lateral surfaces that are substantially vertically arranged. For instance, the substrate 106′ may be a sapphire substrate obtained by utilizing different dicing method, or the substrate 106′ is made by material other than sapphire, so that inclined lateral surfaces are not easily generated on the substrate 106′. Therefore, the included angle 63 defined between the first lateral surfaces S1′ and the first surface 204′ of the third light-emitting element 116′ is within the range of eighty-five to nighty-five degrees, which can be regarded substantially as a right angle. In an embodiment, the third light-emitting element 116′ comprises an aluminum gallium indium phosphide series semiconductor stack 210-3, and the semiconductor stack 210-3 is bonded to the substrate 106′ via a bonding layer (not shown in the figure). The third light-emitting element 116′ generates red light or yellow light.

For the embodiment shown by the first cross-sectional structure 400-1 and the second cross-sectional structure 400-2, their corresponding cross-sectional structure on the Y-Z plane are similar to the cross-sectional structure 300 shown in FIG. 3, so the first pitch P11 can be smaller as well.

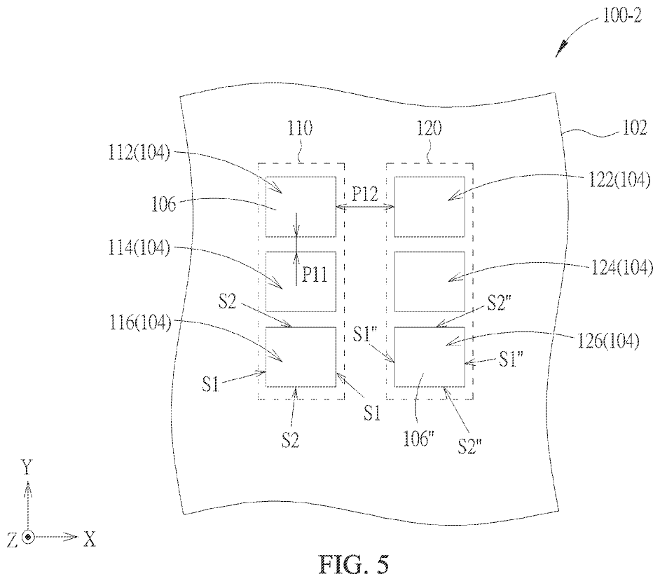

FIG. 5 is an aerial schematic view of the light-emitting device in accordance with an embodiment of the present application. Taking reference to FIG. 5, the light-emitting device 100-2 shown in FIG. 5 can be regarded as a schematic figure of a partial region of the light-emitting device 100-1 shown in FIG. 1. According to an embodiment, the light-emitting device 100-2 comprises a first light-emitting element group 110 adjacent to a second light-emitting element group 120, which can be regarded as pixels of the display device respectively. The constituent parts and their arrangement of the light-emitting elements 104 within the second light-emitting element group 120 may be the same or similar to the constituent parts and their arrangement of the light-emitting elements 104 within the first light-emitting element group 110. According to an embodiment of the present application, the second light-emitting element group 120 comprises a first light-emitting element 122, a second light-emitting element 124, and a third light-emitting element 126. The first, second, and third light-emitting elements 122, 124, 126 emit, but not limited to, blue light, green light, and red light respectively. According to different embodiments of the present application, the arrangement sequence of the first, second, and third light-emitting elements 122, 124, 126 may be adjusted in accordance with practical needs, and the arrangement sequence shall not be limited to it as shown in FIG. 5. Similar to first light-emitting element group 110, each of the substrates 106″ within the second light-emitting element group 120 also has first lateral surfaces S1″ that are paired and second lateral surfaces S2″ that are paired. The first lateral surfaces S1″ may serve as the short sides of the light-emitting elements 104, and the second lateral surfaces S2″ may serve as the long sides of the light-emitting elements 104. The first lateral surfaces S1″ may be on or parallel to the r-plane of the sapphire, while the second lateral surfaces S2″ may be on or parallel to the a-plane of the sapphire. According to an embodiment of the present application, a first shortest pitch P12 is defined by one of the light-emitting elements 104 of the first light-emitting element group 110 and adjacent light-emitting elements 104 of the second light-emitting element group 120. The first shortest pitch P12 is greater than the first pitch P11.

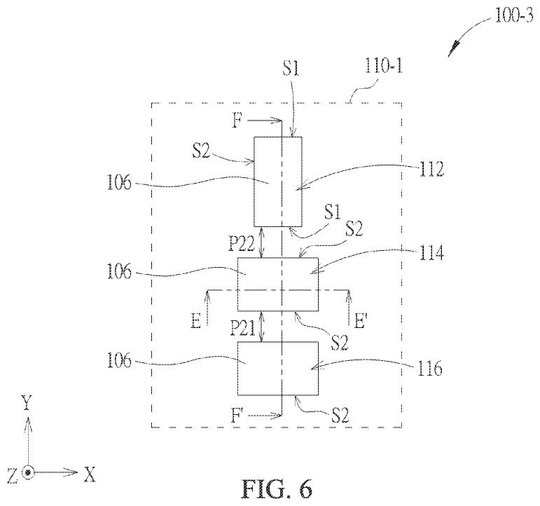

FIG. 6 is an aerial schematic view of the light-emitting device in accordance with an embodiment of the present application. Taking reference to FIG. 6, the light-emitting device 100-3 shown in FIG. 6 can be regarded as a schematic figure of a partial region of the light-emitting device 100-1 shown in FIG. 1. According to an embodiment of the present application, the light-emitting device 100-3 comprises the first light-emitting element group 110-1. As shown in FIG. 6, each of the substrates 106 within the first light-emitting element group 110-1 also has first lateral surfaces S1 that are paired and second lateral surfaces S2 that are paired. In an embodiment, the first lateral surfaces S1 may serve as the short sides of the light-emitting elements 104, and the second lateral surfaces S2 may serve as the long sides of the light-emitting elements 104. One of the second lateral surfaces S2 of the second light-emitting element 114 is adjacent to one of the second lateral surfaces S2 of the third light-emitting element 116, and a second pitch P21 is defined between them. In accordance with the embodiment shown in FIG. 6, one the differences between the first light-emitting element group 110-1 and the first light-emitting element group 110 shown in FIG. 1 is that the second lateral surfaces S2 of the first light-emitting element 112 do not face the second lateral surfaces S2 of the second light-emitting element 114. Instead, one of the first lateral surfaces S1 of the first light-emitting element 112 faces one of the second lateral surfaces S2 of the second light-emitting element 114. A second shortest pitch P22 is defined between the first lateral surface S1 of the first light-emitting element 112 and the adjacent second lateral surface S2 of the second light-emitting elements 114. Similarly, the substrates 106 may be each sapphire substrate or other suitable semiconductor substrate, and each of the first lateral surfaces S1 of the substrates 106 may be on or parallel to a specific crystal face of the sapphire substrate, such as r-plane, while the second lateral surfaces S2 may be on or parallel to another specific crystal face of the sapphire substrate, such as a-plane. According to an embodiment, the first light-emitting element 112, the second light-emitting element 114, and the third light-emitting element 116 are arranged along a first direction, e.g., Y-axis direction, and in the top view of the light-emitting device 100-3, each of the first lateral surfaces S1 of the first light emitting element 112 has a first edge, and each of the first lateral surfaces S1 connects the first surface of the first light-emitting element by the first edge. Each of the second lateral surfaces S2 of the second light-emitting element 114 has a second edge, and each of the second lateral surfaces S2 connects the first surface of the second light-emitting element 114 by the second edge. The extension direction of the first edge of the first light-emitting element 112 is substantially parallel to the extension direction of the second edge of the second light-emitting element 114.

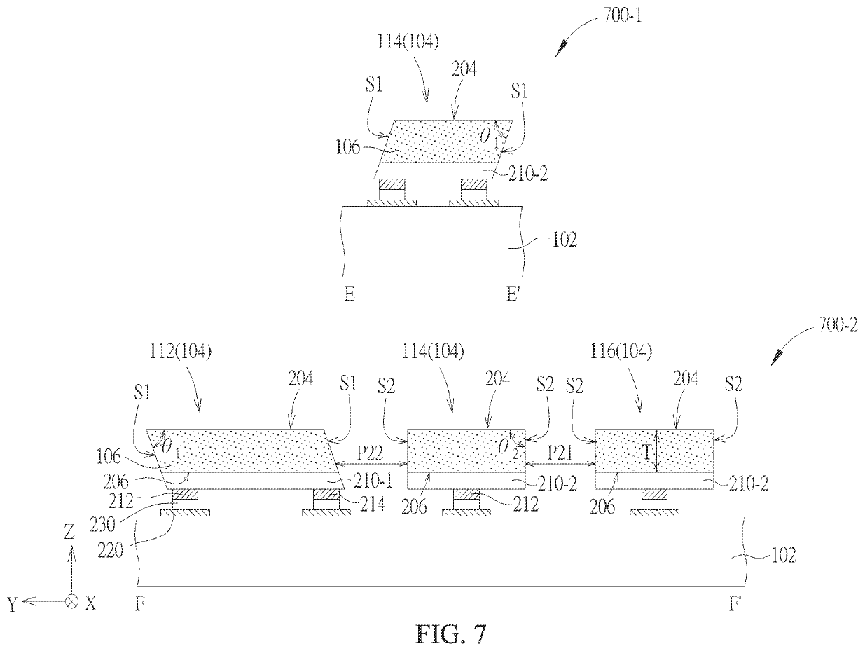

FIG. 7 is a cross-sectional schematic view of the light-emitting device taken along cross-sectional lines E-E′ and F-F′ shown in FIG. 6 in accordance with an embodiment of the present application. The first cross-sectional structure 700-1 corresponds to the cross-sectional line E-E′ of FIG. 6, and the second cross-sectional structure 700-2 corresponds to the cross-sectional line F-F′ of FIG. 6. Taking reference to FIG. 7, the first cross-sectional structure 700-1 is similar to the cross-sectional region of the cross-sectional structure 200 of FIG. 2 corresponding to the cross-sectional line B-B′ of FIG. 1. The second light-emitting element 114 comprises the first surface 204 and the pair of the first lateral surfaces S1 that are inclined to the first surface 204.

Still taking reference to FIG. 7, the second cross-sectional structure 700-2 is similar to the cross-sectional structure 300 in FIG. 3. The substrate 106 of the second light-emitting element 114 and the substrate 106 of the third light-emitting element 116 are also provided with two top angles, which are defined between the second lateral surfaces S2 and the corresponding first surface 204. The top angles (namely the included angle θ₂) are within the range between eighty-five to ninety-five degrees, which can be therefore regarded substantially as a right angle. According to an embodiment of the present application, when the substrate 106 is a sapphire substrate, the second lateral surfaces S2 correspond to or are parallel to the a-plane of the sapphire substrate, while the first surface 204 is parallel to the c-plane of the sapphire substrate. Since the a-plane and the c-plane of the sapphire substrate are vertical to each other, when sapphire substrate is used for the substrates 106 of the second light-emitting element 114 and the third light-emitting element 116, the second light-emitting element 114 and the third light-emitting element 116 thus comprise the first surface 204 and the pair of the second lateral surfaces S2 vertical to the first surface 204. According to an embodiment of the present application, since the second lateral surfaces S2 of adjacent second light-emitting element 114 and the third light-emitting element 116 that face each other are substantially vertical to the first surface 204 rather than inclined to the first surface 204, the pitch, namely a second pitch P21, between the second surfaces S2 of adjacent second light-emitting element 114 and third light-emitting element 116 that face each other can be ranged from 10 μm to 50 μm or any value within the range.

For the first light-emitting element 112 of the cross-sectional structure 700-2, the inclined first lateral surface S1 is adjacent to and faces one of the second lateral surfaces S2 of the second light-emitting element 114. According to an embodiment, when the substrate 106 is a sapphire substrate, the first lateral surfaces S1 correspond to or are parallel to the r-plane of the sapphire substrate, and the first surface 204 is parallel to the c-plane of the sapphire substrate. Since the r-plane and the c-plane of the sapphire substrate are not vertical to each other, when sapphire substrate is used for the substrate 106 of the first light-emitting element 112, the first light-emitting element 112 thus comprises the first surface 204 and the pair of the first lateral surfaces S1 inclined to the first surface 204. The cross-section of the substrate 106 of the first light-emitting element 112 is provided with two top angles, which are defined between the first lateral surfaces S1 and the first surface 204. One of the top angles is an acute angle (namely the included angle θ₁), while the other top angle is an obtuse angle. The acute angle is far from the second light-emitting element 114, and the obtuse angle is adjacent to the second light-emitting element 114. The arrangement described above is not limited to it. A second shortest pitch P22 is defined between the adjacent first lateral surface S1 of the first light-emitting element 112 and the adjacent second lateral surface S2 of the second light-emitting element 114. The second shortest pitch P22 is ranged from 10 μm to 50 μm. In addition, for the relation between the included angle θ₁ and the included angle θ₂, the aforementioned formula (1) is still satisfied.

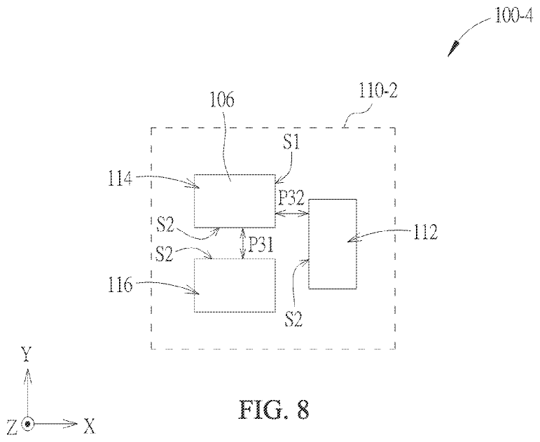

FIG. 8 is an aerial schematic view of the light-emitting device of an embodiment of the present application. Taking reference to FIG. 8, the light-emitting device 100-4 shown in FIG. 8 can be regarded as a schematic figure of a partial region of the first light-emitting device 100-1 shown in FIG. 1. According to an embodiment of the present application, the light-emitting device 100-4 comprises the first light-emitting element group 110-2. The constituent parts and the arrangement of the first light-emitting element group 110-2 are similar to the constituent parts and the arrangement of the first light-emitting element group 110 shown in FIG. 1. As shown in FIG. 8, each of the substrates 106 within the first light-emitting element group 110-2 also has the first lateral surfaces S1 that are paired and the second lateral surfaces S2 that are paired. The first lateral surfaces S1 may serve as the short sides of the light-emitting elements 104, and the second lateral surfaces S2 may serve as the long sides of the light-emitting elements 104. One of the second lateral surfaces S2 of the second light-emitting element 114 is adjacent to one of the second lateral surface S2 of the third light-emitting element 116, and a third pitch P31 is defined between them. In accordance with the embodiment shown in FIG. 8, the second lateral surfaces S2 of the first light-emitting element 112 do not face the second lateral surfaces S2 of the second light-emitting element 114. Instead, one of the second lateral surfaces S2 of the first light-emitting element 112 faces one of the first lateral surfaces S1 of the second light-emitting element 114 and one of the first lateral surfaces S1 of the third light-emitting element 116. A third shortest pitch P32 is defined between one of the second lateral surfaces S2 of the first light-emitting element 112 and the adjacent first lateral surface S1 of the second light-emitting element 114 (or the third light-emitting element 116). Similarly, each of the substrates 106 may be sapphire substrate or other suitable semiconductor substrate, and each of the first lateral surfaces S1 of the substrates 106 may be on or parallel to a specific crystal face of the sapphire substrate, such as r-plane, while the second lateral surfaces S2 may be on or parallel to another specific crystal face of the sapphire substrate, such as a-plane. The pitches P31, P32 between the lateral surfaces of any two adjacent light-emitting elements that face each other may be ranged from 10 μm to 50 μm.

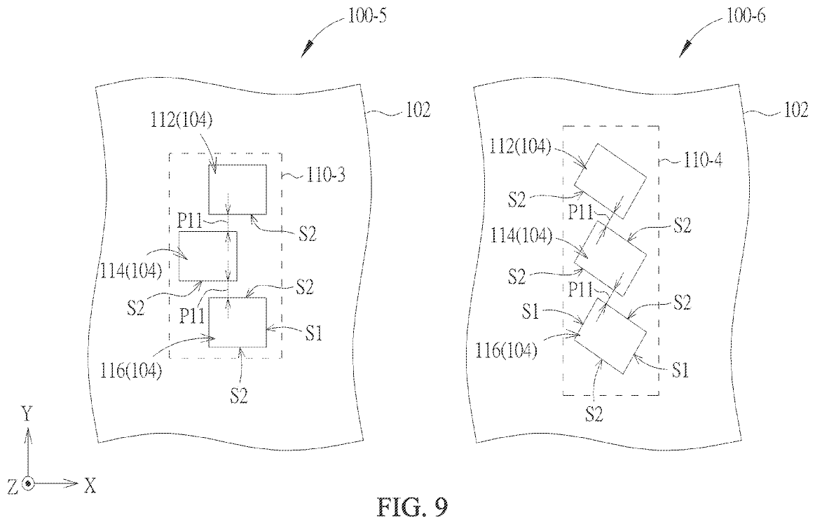

FIG. 9 is an aerial schematic view of the light-emitting device in accordance with some embodiments of the present application. The first light-emitting device 100-5 and the second light-emitting device 100-6 can correspond to different embodiments. For the first light-emitting device 100-5, its constituent parts and arrangement of the first light-emitting element group 110-3 are similar to the constituent parts and arrangement of the first light-emitting element group 110 shown in FIG. 1. The light-emitting elements 104 of the first light-emitting element group 110-3 are arranged along the first direction (e.g., Y-axis direction) as well. One of the differences between them is that one of two adjacent light-emitting elements 104 of the first light-emitting element group 110-3 shifts along a second direction (e.g., X-axis direction), and the second direction is vertical to the first direction. For instance, the second light-emitting element 114 of the first light-emitting element group 110-3 shifts relatively to the first light-emitting element 112 or the third light-emitting element 116 along the second direction.

Still taking reference to FIG. 9, for the second light-emitting device 100-6, its constituent parts and arrangement of the first light-emitting element group 110-4 are similar to the constituent parts and arrangement of the first light-emitting element group 110 shown in FIG. 1. The light-emitting elements 104 of the first light-emitting element group 110-4 are also arranged along the first direction (e.g., Y-axis direction). One of the differences between them is that each of the first lateral surfaces S1 has a first edge, and each of the second lateral surfaces S2 has a second edge. The first surface connects each of the first lateral surfaces S1 by the first edge, and the first surface connects each of the second lateral surfaces S2 by the second edge. The extension direction of the of the first edge of the light-emitting element 104 and the extension direction of the second edge of the light-emitting elements 104 are not parallel to the first direction (e.g., Y-axis direction). For instance, each of the light-emitting elements 104 rotates clockwise or counterclockwise with an angle about a rotation axis that is the Z-axis shown in FIG. 9.

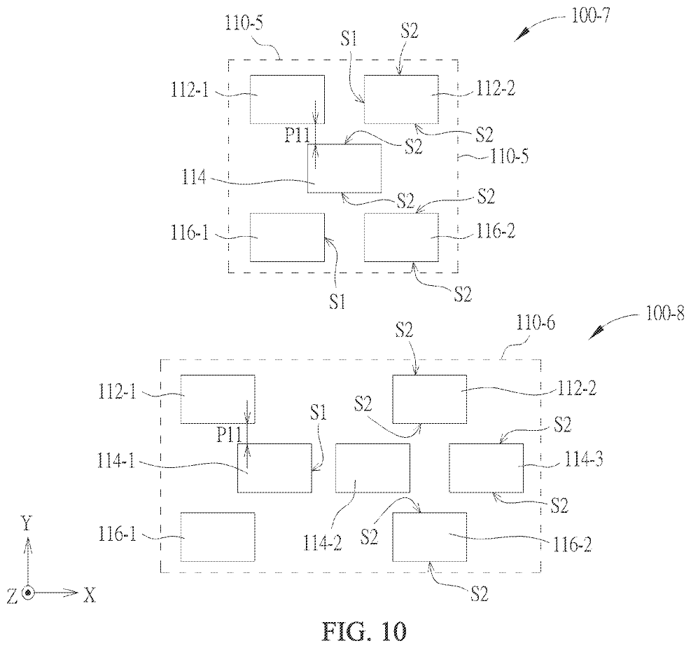

FIG. 10 is an aerial schematic view of the light-emitting device in accordance with some embodiments of the present application. The first light-emitting device 100-7 and the second light-emitting device 100-8 can correspond to different embodiments. For the first light-emitting device 100-7, its constituent parts and arrangement of the first light-emitting element group 110-5 are similar to the constituent parts and arrangement of the first light-emitting element group 110 shown in FIG. 1. One of the differences between them is that the first light-emitting element group 110-5 comprises two of the first light-emitting elements 112-1, 112-2, and the inclined first lateral surfaces S1 of the adjacent two of the first light-emitting elements 112-1, 112-2 face each other. The first light-emitting element group 110-5 comprises two of the third light-emitting elements 116-1, 116-2, and the inclined first lateral surfaces S1 of the adjacent two of the third light-emitting elements 116-1, 116-2 face each other. The first light-emitting element group 110-5 comprises only one second light-emitting element 114. The second light-emitting element 114 and the first light-emitting elements 112-1, 112-2 are overlapped partially or entirely in Y-axis direction. One of the second lateral surfaces S2 of the second light-emitting element 114 faces one of the second lateral surfaces S2 of the first light-emitting elements 112-1, 112-2. The second light-emitting element 114 and the third light-emitting elements 116-1, 116-2 are overlapped partially or entirely in Y-axis direction. The other second lateral surface S2 of the second light-emitting element 114 faces one of the second lateral surfaces S2 of the third light-emitting elements 116-1, 116-2.

Still taking reference to FIG. 10, for the second light-emitting device 100-8, the constituent parts and arrangement of the first light-emitting element group 110-6 are similar to the constituent parts and arrangement of the first light-emitting element group 110 shown in FIG. 1. One of the differences between them is that the first light-emitting element group 110-6 comprises two of the first light-emitting elements 112-1, 112-2, and the inclined first lateral surfaces S1 of the adjacent two of the first light-emitting elements 112-1, 112-2 face each other. The first light-emitting element group 110-6 comprises two of the third light-emitting elements 116-1, 116-2, and the inclined first lateral surfaces S1 of the adjacent two of the third light-emitting elements 116-1, 116-2 face each other. The first light-emitting element group 110-6 comprises three of the second light-emitting elements 114-1, 114-2, 114-3. Similar to the first light-emitting element group 110-5, one or more of the second light-emitting elements 114-1, 114-2, 114-3 partially or entirely overlap the first light-emitting elements 112-1, 112-2 in Y-axis direction. One of the second lateral surfaces S2 of the second light-emitting element 114-1 faces one of the second lateral surfaces S2 of the first light-emitting elements 112-1. One of the second lateral surfaces S2 of the second light-emitting element 114-2, 114-3 faces one of the second lateral surfaces S2 of the first light-emitting elements 112-2. One or more of the second light-emitting elements 114-1, 114-2, 114-3 partially or entirely overlap the first light-emitting elements 112-1, 112-2 in Y-axis direction. The other second lateral surface S2 of the second light-emitting element 114-1 faces one of the second lateral surfaces S2 of the third light-emitting elements 116-1. The other second lateral surfaces S2 of the second light-emitting elements 114-2, 114-3 each face one of the second lateral surfaces S2 of the third light-emitting elements 116-2.

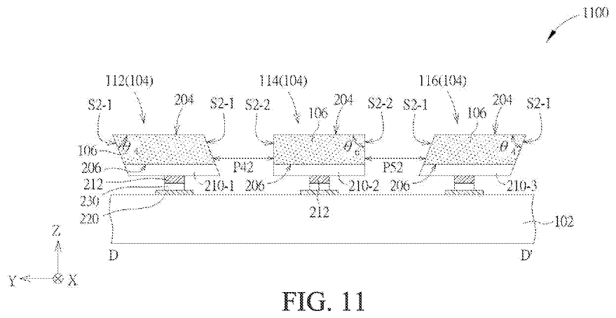

FIG. 11 is a cross-sectional schematic view of the light-emitting device taken along the cross-sectional lines D-D′ shown in FIG. 1 in accordance with an embodiment of the present application. Taking reference to FIG. 11, which is a cross-sectional view of the first light-emitting element 112, the second light-emitting element 114, and the third light-emitting element 116 of a cross-sectional structure 1100 on the Y-Z plane. The constituent parts and the arrangement of the cross-sectional structure 1100 are similar to the cross-sectional structure 300 shown in FIG. 3, but they belong to different embodiments.

As the embodiment shown by the cross-sectional structure 1100, the substrate 106 of the first light-emitting element 112 comprises the second lateral surfaces S2-1 that are oppositely arranged, and two top angles are defined between the first lateral surface 204 and the second lateral surfaces S2-1. One of the top angles is an acute angel (namely the included angle θ₄), while the other top angle is an obtuse angle. Similarly, the substrate 106 of the third light-emitting element 116 comprises the second lateral surfaces S2-1 that are oppositely arranged and two top angles are defined between the first lateral surface 204 and the second lateral surfaces S2-1. One of the top angles is an acute angle (namely the included angle θ₄), while the other top angle is an obtuse angle. In addition, the substrate 106 of the second light-emitting element 114 comprises the second lateral surfaces S2-2 that are oppositely arranged and two top angles are defined between the first lateral surface 204 and the second lateral surfaces S2-2. The top angles (namely the included angle θ₆) are ranged from eighty-five to ninety-five degrees, which can be regarded substantially as a right angle.

According to an embodiment of the present application, the included angles θ₄ of the first light-emitting element 112 and the third light-emitting element 116 is less than the included angle θ₆ of the second light-emitting element 114. According to an embodiment of the present application, when the substrates 106 of the first light-emitting element 112 and the third light-emitting element 116 are sapphire substrates, the second lateral surfaces S2-1 of the first light-emitting element 112 and the third light-emitting element 116 correspond to or are parallel to the r-plane of the sapphire substrate. In addition, in accordance with an embodiment of the present application, the substrate 106 of the second light-emitting element 114 may be a sapphire substrate obtained by means of different dicing method, or the substrate 106 may be made by other material other than sapphire, so that the second lateral surfaces S2-2 of the second light-emitting element 114 are unlikely to be inclined.

Still taking reference to FIG. 11, the top angle (which is an acute angle) of the substrate 106 of the first light-emitting element 112 is far from the top angle (which is an acute angle) of the substrate 106 of the third light-emitting element 116, while the top angle (which is an obtuse angle) of the substrate 106 of the first light-emitting element 112 faces the top angle (which is an obtuse angle) of the substrate 106 of the third light-emitting element 116. A fourth shortest pitch P42 is defined between the adjacent second lateral surface S2-1 of the first light-emitting element 112 and the adjacent second lateral surface S2-2 of the second light-emitting element 114, and a fifth shortest pitch P52 is defined between the adjacent second lateral surface S2-1 of the third light-emitting element 116 and the adjacent second lateral surface S2-2 of the second light-emitting element 114. The fourth shortest pitch P42 and the fifth shortest pitch P52 are ranged from 10 μm to 50 μm.

When die bonder is utilized to mount the light-emitting elements 104 on the circuit carrier board 102, since the top angles, which are acute angles, of each of the substrates 106 of the first light-emitting element 112 and the third light-emitting element 116 are far from the second lateral surfaces S2-2 of the second light-emitting element 114, the occurring possibility or the degree of alignment error can be reduced, further preventing adjacent light-emitting elements 104 from collision due to the inclined lateral surfaces of their substrates 106. Therefore, in accordance with an embodiment of the present application, even the fourth shortest pitch P42 and the fifth shortest pitch P52 are ranged from 10 μm to 50 μm, the production yield rate and product reliability are still not impacted.

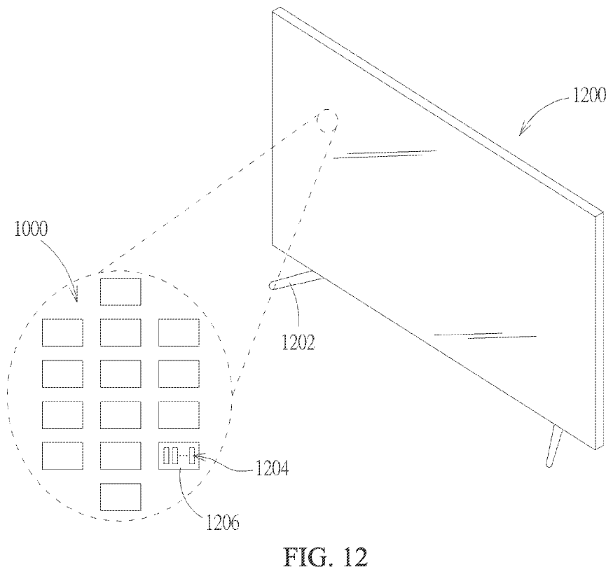

FIG. 12 shows a perspective schematic view of the display device in accordance with an embodiment of the present application. Taking reference to FIG. 12, the display device 1200 is supported by a stand 1200 and comprises a plurality of light-emitting device 1000. The structure of the light-emitting device 1000 is similar to the light-emitting devices 100-1 to 100-8 of each of the aforementioned embodiments. The light-emitting device 1000 comprises a plurality of light-emitting elements 1204. Their structures are similar to the light-emitting elements 104 of the aforementioned embodiments. The light-emitting elements 1204 can be clustered into different light-emitting element groups 1206, so that each of the light-emitting element groups 1206 of the light-emitting device 1000 can constitute each of the pixels of the display device 1200.

In the conventional arts, the lateral surfaces of the sapphire substrate, that are prone to generate oblique crack due to its lattice structure, have two adjacent substrate lateral surfaces of the light-emitting elements of the light-emitting element group that face each other. During the bonding process of bonding two adjacent light-emitting elements to the circuit carrier board, collision may happen due to their pitch and the aforementioned oblique crack. In the embodiments of the present application, the specific crystal face of the sapphire substrate serves as the substrate lateral surfaces of any two adjacent light-emitting elements of the light-emitting element group that face each other, the aforementioned problem of conventional arts is alleviated and the production yield rate of the light-emitting element group is enhanced. In addition, compared to conventional arts, the display device constituted by the light-emitting elements in accordance with the embodiments of the present application can have smaller sub-pixel pitch and smaller pixel pitch, enhancing the display quality of the display device.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting device, comprising:
a circuit carrier board; and
a first light-emitting element group, comprising a plurality of light-emitting elements on the circuit carrier board;
wherein each of the plurality of light-emitting elements comprises a substrate; the substrate comprises a first surface, a second surface opposite to the first surface and facing the circuit carrier board, first lateral surfaces that are paired and oppositely arranged, and second lateral surfaces that are paired and oppositely arranged; each of the second lateral surfaces comprises an edge and connects the first surface by the edge;
wherein the plurality of light-emitting elements is arranged on the circuit carrier board along a first direction, and any adjacent two of the plurality of light-emitting elements are provided with the second lateral surfaces that face each other; the first direction is not parallel to the edge of one of the second lateral surfaces of one of the adjacent two of the plurality of light-emitting elements, and one of the adjacent two of the plurality of light-emitting elements satisfies a formula (1) described below:

|θ₁−90°|>|θ₂−90°| (1)
wherein the θ₁ is an included angle between one of the first lateral surfaces and the first surface of the one of the adjacent two of the plurality of light-emitting elements, and the θ₂ is an included angle between one of the second lateral surfaces and the first surface of the one of the adjacent two of the plurality of light-emitting elements.

2. The light-emitting device claimed in claim 1, wherein a material of the substrate comprises sapphire, each of the first lateral surfaces comprises a r-plane surface of the sapphire, and each of the second lateral surfaces comprises an a-plane surface of the sapphire.

3. The light-emitting device claimed in claim 1, further comprising a first pitch between the second lateral surfaces that face each other, and the first pitch is ranged between 10 μm and 50 μm.

4. The light-emitting device claimed in claim 3, further comprising a second light-emitting element group, which comprises a plurality of light-emitting elements on the circuit carrier board, the plurality of light-emitting elements within the first light-emitting element group and the plurality of light-emitting elements within the second light-emitting element group are both arranged along the first direction, a first shortest pitch is between one of the plurality of light-emitting elements of the first light-emitting element group and one of the plurality of light-emitting elements of the second light-emitting element group, and the first shortest pitch is greater than the first pitch.

5. The light-emitting device claimed in claim 1, wherein the substrate has a thickness which is not less than 40 μm and not greater than 100 μm, and/or the substrate has a diagonal not greater than 300 μm.

6. The light-emitting device claimed in claim 1, wherein each of the plurality of light-emitting elements comprises a semiconductor stack formed on the second surfaces and an electrode electrically connected to the semiconductor stack, the light-emitting device further comprises a plurality of electrode pads on the circuit carrier board and a plurality of electric conducting connection layers, wherein each of the plurality of electric conducting connection layers connects the electrode of each of the plurality of light-emitting elements and each of the plurality of electrode pads.

7. The light-emitting device claimed in claim 1, wherein each of the adjacent two of the plurality of light-emitting elements comprises one or multiple modified trace units on one of the first lateral surfaces and one of the second lateral surfaces, the one or multiple modified trace units comprise a first quantity greater than a second quantity of the modified trace units on the second lateral surfaces.

8. The light-emitting device claimed in claim 1, wherein the included angle θ2 is between eighty-five degrees and ninety-five degrees.

9. The light-emitting device claimed in claim 1, wherein the plurality of light-emitting elements comprises a first light-emitting element and a second light-emitting element that are arranged on the circuit carrier board along the first direction, and wherein the first light-emitting element group further comprises a third light-emitting element on the circuit carrier board, the third light-emitting element comprises a substrate comprising a third surface, a fourth surface opposite to the third surface and facing the circuit carrier board, a third lateral surfaces that are paired and oppositely arranged, and a fourth lateral surfaces that are paired and oppositely arranged, one of the second lateral surfaces of the first light-emitting element faces one of the second lateral surfaces of the second light-emitting element, and the second light-emitting element satisfies the formula (1).

10. The light-emitting device claimed in claim 9, wherein the first light-emitting element, the second light-emitting element, and the third light-emitting element are arranged along the first direction, wherein the other one of the second lateral surfaces of the second light-emitting element faces one of the fourth lateral surfaces of the third light-emitting element, wherein each of the first lateral surfaces comprise a length less than a length of each of the second lateral surfaces, and each of the third lateral surfaces comprise a length less than a length of each of the fourth lateral surfaces, and wherein one of the first lateral surfaces of the second light-emitting element is provided with a first inclination direction, and one of the third lateral surfaces of the third light-emitting element is provided with a second inclination direction, the first inclination direction is opposite to the second inclination direction.

11. The light-emitting device claimed in claim 9, wherein the first light-emitting element, the second light-emitting element, and the third light-emitting element are arranged along the first direction, wherein each of the first lateral surfaces comprise a length less than a length of each of the second lateral surfaces, and each of the third lateral surfaces comprise a length less than a length of each of the fourth lateral surfaces, wherein the other one of the second lateral surfaces of the second light-emitting element faces one of the fourth lateral surfaces of the third light-emitting element, and wherein the third light-emitting element comprises an included angle θ₃ between one of the third lateral surfaces and the third surface of the third light-emitting element, the included angle θ₁ is an acute angle or an obtuse angle, and the included angle θ₃ is a right angle substantially.

12. The light-emitting device claimed in claim 9, wherein the first light-emitting element, the second light-emitting element, and the third light-emitting element are arranged along the first direction, and the third light-emitting element is adjacent to the second light-emitting element, wherein each of the first lateral surfaces comprise a length less than a length of each of the second lateral surfaces, and each of the third lateral surfaces comprise a length less than a length of each of the fourth lateral surfaces, wherein the other one of the second lateral surfaces of the second light-emitting element faces one of the third lateral surfaces of the third light-emitting element.

13. The light-emitting device claimed in claim 9, wherein each of the first lateral surfaces comprise a length less than a length of each of the second lateral surfaces, and each of the third lateral surfaces comprise a length less than a length of each of the fourth lateral surfaces, and wherein one of the fourth lateral surfaces of the third light-emitting element faces one of the first lateral surfaces of the first light-emitting element or one of the first lateral surfaces of the second light-emitting element.

14. The light-emitting device claimed in claim 9, wherein the first light-emitting element, the second light-emitting element, and the third light-emitting element are arranged along the first direction, wherein each of the first lateral surfaces comprise a length less than a length of each of the second lateral surfaces, and each of the third lateral surfaces comprise a length less than a length of each of the fourth lateral surfaces, wherein the other one of the second lateral surfaces of the second light-emitting element faces one of the fourth lateral surfaces of the third light-emitting element, and wherein one of the first light-emitting element, the second light-emitting element, and the third light-emitting element shifts along a second direction, and the second direction is vertical to the first direction.

15. The light-emitting device claimed in claim 9, wherein the first light-emitting element, the second light-emitting element, and the third light-emitting element are arranged along the first direction, wherein each of the first lateral surfaces comprise a length less than a length of each of the second lateral surfaces, and each of the third lateral surfaces comprise a length less than a length of each of the fourth lateral surfaces, wherein the other one of the second lateral surfaces of the second light-emitting element faces one of the fourth lateral surfaces of the third light-emitting element, wherein each of the first light-emitting element, the second light-emitting element, and the third light-emitting element rotates with an angle about a rotation axis, and the rotation axis is vertical to the first surface.

16. The light-emitting device claimed in claim 9, wherein the first light-emitting element group further comprises another one or more of the first light-emitting elements, another one or more of the second light-emitting elements, and/or another one or more of the third light-emitting elements, the first light-emitting element and the another one or more of the first light-emitting elements are arranged along a second direction, the second light-emitting element and the another one or more of the second light-emitting elements are arranged along the second direction, the third light-emitting element and the another one or more of the third light-emitting elements are arranged along the second direction, the first light-emitting elements and the second light-emitting elements are overlapped partially or entirely in the first direction, and/or the second light-emitting elements and the third light-emitting elements are overlapped partially or entirely in the first direction, the second direction is vertical to the first direction.

17. The light-emitting device claimed in claim 9, wherein the first light-emitting element generates light with a first wavelength, the second light-emitting element generates light with a second wavelength and the third light-emitting element generate light with a third wavelengths, wherein the third wavelength is greater than the first wavelength and/or the second wavelength.

18. A display device, comprising a plurality of pixels, wherein the plurality of pixels each comprise the light-emitting device claimed in claim 1.
